(19) United States
(12) Patent Application Publication
(10) Pub. No.: US 2023/0080796 A1
(43) Pub. Date: Mar. 16, 2023

(54) RADIATION-EMITTING COMPONENT HAVING A CONVERTER LAYER AND METHOD FOR PRODUCING A RADIATION-EMITTING COMPONENT HAVING A CONVERTER LAYER

(71) Applicant: OSRAM Opto Semiconductors GmbH, Regensburg (DE)

(72) Inventors: Britta Goeoetz, Regensburg (DE); Markus Burger, Laaber (DE)

(21) Appl. No.: 17/759,246

(22) PCT Filed: Jan. 13, 2021
(86) PCT No.: PCT/EP2021/050528

§ 371 Date: Jul. 21, 2022

(30) Foreign Application Priority Data
Jan. 22, 2020 (DE) 10 2020 101 470.8

(51) Int. Cl. H01L 33/50; H01L 25/075; H01L 27/146; H01L 33/60

(52) U.S. Cl. CPC H01L 33/505; H01L 25/0753; H01L 27/14621; H01L 27/14627; H01L 33/60

(57) ABSTRACT

In an embodiment a component includes a semiconductor chip, a converter layer and a grid structure, wherein the semiconductor chip is configured to generate electromagnetic radiation, wherein the converter layer is configured to convert at least one portion of the electromagnetic radiation, wherein the grid structure is configured to suppress lateral optical crosstalk, the grid structure having a grid frame and openings enclosed by the grid frame, wherein the grid structure only adjoins the converter layer, wherein the openings of the grid structure are free of a material of the converter layer, and wherein optical elements are arranged in the openings.

This patent application is a national phase filing under section 371 of PCT/EP2021/050528, filed Jan. 13, 2021, which claims the priority of German patent application 10 2020 101 470.8, filed Jan. 22, 2020, each of which is incorporated herein by reference in its entirety.

### TECHNICAL FIELD

A component, in particular an optoelectronic component having a converter layer, is specified. Furthermore, a method for producing a component, in particular a component described here, is specified.

### BACKGROUND

In the case of optoelectronic components which find application in display devices, in particular, it is often desirable for the components to have or form clearly defined picture elements, i.e. clearly defined pixels. Excessive optical crosstalk in a common layer, for instance in a common converter layer, covering a plurality of pixels, should therefore be avoided as far as possible.

One possibility for minimizing optical crosstalk consists in making the converter layer as thin as possible. However, this can result in inadequate conversion of electromagnetic radiations, which in turn results in a poor color rendering index or in inadequate efficiency of the component.

### SUMMARY

Embodiments provide a compact and efficient optoelectronic component having high color contrast which is able to be produced in a simplified manner. Further embodiments provide a reliable and cost-effective method for producing a component.

In accordance with at least one embodiment of a component, the latter has a semiconductor chip, a converter layer and a grid structure, wherein the semiconductor chip is configured for generating electromagnetic radiation, the converter layer is provided for converting radiation of short wavelength into radiation of long wavelength, and the grid structure is arranged on the semiconductor chip. The grid structure can be arranged within the converter layer or adjoin the converter layer, in particular directly adjoin the converter layer. Moreover it is possible for the grid structure to be spaced apart vertically from the converter layer or from the semiconductor chip by a connection layer, for instance. Furthermore, it is possible for the connection layer to be embodied as a partial layer of the converter layer. The grid structure has a grid frame configured for suppressing, in particular for reducing, optical crosstalk. The grid structure can have openings surrounded, in particular completely surrounded, by the grid frame in lateral directions.

A vertical direction is understood to mean a direction that is directed in particular perpendicular to a main surface of extent of the converter layer or of the grid structure. A lateral direction is understood to mean a direction that runs in particular parallel to the main surface of extent. The vertical direction and the lateral direction are orthogonal to one another.

In accordance with at least one embodiment of the component, the grid structure is formed from a radiation-reflecting material or from a radiation-absorbing material. It is possible for the material of the grid structure to comprise radiation-absorbing and/or radiation-reflecting particles. In particular, the grid structure is embodied with regard to its material composition or layer thickness in such a way that the grid structure reflects or absorbs at least 50%, 60%, 70% or at least 80%, for instance between 50% and 95% inclusive, of the radiation intensity impinging on it for instance in the visible spectral range.

In accordance with at least one embodiment of the component, the connection layer is situated in the vertical direction between the semiconductor chip and the converter layer or between the converter layer and the grid structure. In particular, the grid structure is a prefabricated structure that is secured on the semiconductor chip by means of the connection layer. In other words, the grid structure is produced separately from the semiconductor chip before the grid structure is applied to the semiconductor chip. The converter layer can be applied directly to the semiconductor chip or can firstly be formed on the grid structure before the converter layer together with the grid structure is secured on the semiconductor chip in particular by means of the connection layer.

In accordance with at least one embodiment of the component, the connection layer is formed from an electrically insulating material. The connection layer can be an adhesive layer. In particular, the connection layer is embodied with regard to its material composition and layer thickness in such a way that it has a transmittance of at least 50%, 60%, 70%, 80% or 90% with regard to the electromagnetic radiation generated by the semiconductor chip or the electromagnetic radiation converted by the converter layer. For example, the transmittance is between 50% and 99% inclusive or between 60% and 95% inclusive.

In accordance with at least one embodiment of the component, the connection layer is embodied as an independent layer or as a partial layer of the converter layer. If the connection layer is embodied as an independent layer, the connection layer and the converter layer can differ from one another with regard to the material composition. For example, the connection layer is free of phosphor particles or, in comparison with the converter layer, contains only small traces of phosphor particles configured for converting electromagnetic radiation. If the connection layer is embodied as a partial layer of the converter layer, the connection layer can be integrated in the converter layer. In particular, the connection layer and the converter layer can be formed from an identical matrix material. Moreover, it is possible for the connection layer and the converter layer to have an identical material composition.

In at least one embodiment of a component, the latter has a semiconductor chip, a converter layer and a grid structure, wherein the semiconductor chip is configured for generating electromagnetic radiation during operation of the component. The converter layer is configured for converting at least one portion of the electromagnetic radiation generated by the semiconductor chip. The grid structure is configured for suppressing lateral optical crosstalk, wherein the grid structure has a grid frame and openings enclosed by the grid frame.

In accordance with at least one embodiment of the component, the latter has an electrically insulating and radiation-transmissive connection layer arranged in a vertical direction between the semiconductor chip and the grid structure. The connection layer can be embodied as an independent layer or as a partial layer of the converter layer.

Since the connection layer is configured for securing the grid structure on the semiconductor chip and is situated in the vertical direction between the semiconductor chip and the grid structure, the grid structure can be prefabricated independently of the semiconductor chip and subsequently secured on the semiconductor chip. The grid structure serves in particular for the segmentation or the subdivision of the converter layer and can be produced separately from the semiconductor chip. In comparison with the realization of a grid structure on a semiconductor chip at the wafer level, for instance, the separate handling of the converter layer results in reliable and simplified process management. In particular, the grid structure and possibly the converter layer can be tested and characterized in regard to their quality or color locus properties before the grid structure is transferred to the semiconductor chip.

In particular, the component is free of a metallic layer or free of a metal layer, for instance free of a seed layer, arranged in the vertical direction between the semiconductor chip and the grid structure.

In accordance with at least one embodiment of the component, the grid structure is formed from an electrically insulating material. For example, the grid structure is formed from a resist material, for instance from a photoresist, a plastic or from a polymer.

In accordance with at least one embodiment of the component, the grid structure is formed from an electrically conductive material. It is possible for the grid structure to be formed from a metal, for instance from Al, Au or Ni.

In accordance with at least one embodiment of the component, the semiconductor chip has a continuous semiconductor body embodied in a segmented fashion. The semiconductor chip has a plurality of individually controllable partial regions, each assigned to one of the openings of the grid structure and configured for generating electrical radiation during operation of the component.

The semiconductor body can have a first semiconductor layer, a second semiconductor layer and an active zone arranged between the first and second semiconductor layers. The active zone is embodied in particular in a segmented fashion and has a plurality of individually controllable active partial regions. One of the semiconductor layers, for example the first or the second semiconductor layer, can be embodied in a continuous fashion. The other of the first and second semiconductor layers can be embodied in a segmented fashion and have a plurality of individually controllable partial regions.

In accordance with at least one embodiment of the component, the semiconductor chip has a plurality of semiconductor bodies spatially separated from one another and configured for generating electrical radiation during operation of the component. The spatially separated semiconductor bodies are in particular each assigned to one of the openings of the grid structure. For example, the semiconductor chip has a common carrier, on which a plurality of spatially separated semiconductor bodies are arranged. The spatially separated semiconductor bodies can be constructed in an identical way or differently. For example, the separated semiconductor bodies can be configured for generating electromagnetic radiations having an identical peak wavelength or different peak wavelengths.

In accordance with at least one embodiment of the component, the grid structure extends into the converter layer or through the converter layer, such that the openings of the grid structure are filled by the material of the converter layer. If the grid structure extends only into, and not through, the converter layer, the converter layer can furthermore be embodied in a continuous fashion. If the grid structure extends through the converter layer, it is possible for the converter layer thereby to be divided into a plurality of partial layers and thus to have a plurality of laterally spaced apart partial layers.

In accordance with at least one embodiment of the component, the grid structure only adjoins the converter layer, wherein the openings of the grid structure are free of a material of the converter layer. In particular, optical elements are arranged in the openings of the grid structure. In this case, it is possible for the grid structure not to extend into the converter layer or through the converter layer.

In accordance with at least one embodiment of the component, the optical elements extend regionally into the converter layer. For example, the optical elements are embodied as lenses. The optical elements can have curved surfaces that directly adjoin the converter layer.

In accordance with at least one embodiment of the component, the connection layer is arranged in a vertical direction between the converter layer and the grid structure. Consequently, the grid structure is spaced apart vertically from the converter layer, in particular. In other words, the grid structure is spatially separated from the converter layer by the connection layer.

In accordance with at least one embodiment of the component, the openings each have a maximum lateral extent that is between 0.5 μm and 5 cm inclusive, for example between 0.5 μm and 1 cm inclusive, between 0.5 μm and 1 mm inclusive, between 1 μm and 1 mm inclusive or between 10 μm and 1 mm inclusive.

The maximum lateral extent of the respective openings defines in particular the size of the associated picture element or pixel of the component. For example, the component has a front side having a maximum lateral extent of between 1 mm and 10 cm inclusive, for instance between 1 mm and 5 cm inclusive, or between 1 mm and 1 cm inclusive. In particular, the semiconductor chip is embodied in a pixelated fashion. The semiconductor chip can be embodied in a continuous fashion. However, the component can have larger lateral extents. It is possible for the component to have a plurality of semiconductor chips or to have one semiconductor chip having a plurality of separated semiconductor bodies or partial regions (FIG. 10E).

In accordance with at least one embodiment of the component, the semiconductor chip has a marking structure defining boundaries between different partial regions of the semiconductor chip. The partial regions of the semiconductor chip can each be assigned to one, for instance exactly one, of the openings of the grid structure, and in particular vice versa.

The marking structure can be embodied in the form of a separating structure that physically separates the different partial regions of the semiconductor chip or of the semiconductor body from one another. For example, the separating structure has a system of separating trenches formed in the semiconductor body of the semiconductor chip for the purpose of subdividing the semiconductor chip. In the case of a segmented or pixelated semiconductor chip, it is possible for the separating structure to divide the semiconductor body into a plurality of laterally spaced apart partial regions. Alternatively, it is possible for at least one of the semiconductor layers of the semiconductor body which extends laterally over all partial regions of the semiconductor body to still remain continuous, while other semiconductor layers, in particular the active zone of the semiconductor body, are segmented by the marking structure or by the separating structure. Moreover, it is possible for the marking structure to be formed by roughening a surface of the semiconductor body.

In accordance with at least one embodiment of the component, the connection layer is formed from an adhesive material. The adhesive material can be an adhesive silicone. Scattering particles or reflection particles can be embedded in the adhesive material. In particular, the connection layer is different than the converter layer.

In one embodiment of an electronic device, the latter contains the component described here. The electronic device can be a display device, display, touchpad, smartphone, cell phone or a system of LEDs, sensors, laser diodes and/or detectors. The component can additionally find application in a light source for general lighting, for instance for interior or exterior lighting.

In at least one embodiment of a method for producing a component, a semiconductor chip configured for generating electromagnetic radiation during operation of the component is provided. An auxiliary carrier is additionally provided. A grid structure is formed on the auxiliary carrier, wherein the grid structure is configured for suppressing lateral optical crosstalk. The grid structure has a grid frame and also openings enclosed by the grid frame. A converter layer is formed in particular on the semiconductor chip or on the grid structure. The grid structure is connected to the semiconductor chip. For example, the grid structure is connected to the semiconductor chip by means of an electrically insulating and radiation-transmissive connection layer, wherein the connection layer is arranged in a vertical direction between the semiconductor chip and the grid structure.

The grid structure is thus prefabricated separately from the semiconductor chip and subsequently secured on the semiconductor chip. In this case, it is possible for the converter layer to be applied directly to the semiconductor chip or firstly to be applied to the grid structure and subsequently to be secured together with the grid structure on the semiconductor chip.

In accordance with at least one embodiment of the method, the auxiliary carrier is removed from the component after the process of connecting the grid structure to the semiconductor chip.

In accordance with at least one embodiment of the method, the auxiliary carrier is removed from the grid structure before the process of connecting the grid structure to the semiconductor chip. In particular, the auxiliary carrier is a temporary carrier that is removed from the grid structure after the grid structure is applied to a further auxiliary carrier or is transferred by adhesive bonding thereon.

In accordance with at least one embodiment of the method, before the process of connecting the grid structure to the semiconductor chip, the converter layer is formed on the grid structure. The openings of the grid structure can be filled by a material of the converter layer. After the process of connecting the grid structure to the semiconductor chip, the connection layer is arranged for instance between the converter layer and the semiconductor chip.

In accordance with at least one embodiment of the method, optical elements are formed in the openings of the grid structure. Before the process of connecting the grid structure to the semiconductor chip, the converter layer can be formed on the grid structure and on the optical elements. After the process of connecting the grid structure to the semiconductor chip, the connection layer is arranged for instance between the converter layer and the semiconductor chip.

In accordance with at least one embodiment of the method, before the process of connecting the grid structure to the semiconductor chip, the converter layer is formed on the semiconductor chip. After the process of connecting the grid structure to the semiconductor chip, the connection layer is arranged for instance between the converter layer and the grid structure.

In accordance with at least one embodiment of the method, the auxiliary carrier provided is a temporary carrier. After the process of forming the grid structure on the temporary carrier, a further auxiliary carrier can be applied to the grid structure, such that the grid structure is situated between the temporary carrier and the further auxiliary carrier. The temporary carrier is removed from the grid structure, in particular before the grid structure in particular together with the further auxiliary carrier is connected to the semiconductor chip by means of the connection layer.

The methods described above are particularly suitable for producing a component described here. The features described in association with the component can therefore be used for the methods, and vice versa.

### BRIEF DESCRIPTION OF THE DRAWINGS

Further embodiments and configurations of the component or of the method for producing the component will become apparent from the exemplary embodiments explained below in association with FIGS. 1A to 10E, in which:

FIGS. 1A and 1B show schematic illustrations of a first exemplary embodiment of a component in sectional view and in plan view;

FIGS. 2, 3, 4 and 5 show schematic illustrations of further exemplary embodiments of a component in sectional views;

FIGS. 6A, 6B, 6C, 6D and 6E show schematic illustrations of some method steps in accordance with a first exemplary embodiment of a method for producing a component;

FIGS. 7A, 7B, 7C, 7D and 7E show schematic illustrations of some method steps in accordance with a second exemplary embodiment of a method for producing a component;

FIGS. 8A, 8B, 8C, 8D, 8E, 9A, 9B, 9C, 9D and 9E show schematic illustrations of some method steps in accordance with further exemplary embodiments of a method for producing a component; and

FIGS. 10A, 10B, 10C, 10D and 10E show schematic illustrations of further exemplary embodiments of a component or of a semiconductor chip with a converter layer arranged thereon in sectional views.

### DETAILED DESCRIPTION OF ILLUSTRATIVE EMBODIMENTS

Elements that are identical, of identical type or act identically are provided with identical reference signs in the figures. The figures are in each case schematic illustrations and therefore not necessarily true to scale. Rather, comparatively small elements and in particular layer thicknesses may be illustrated with an exaggerated size for clarification.

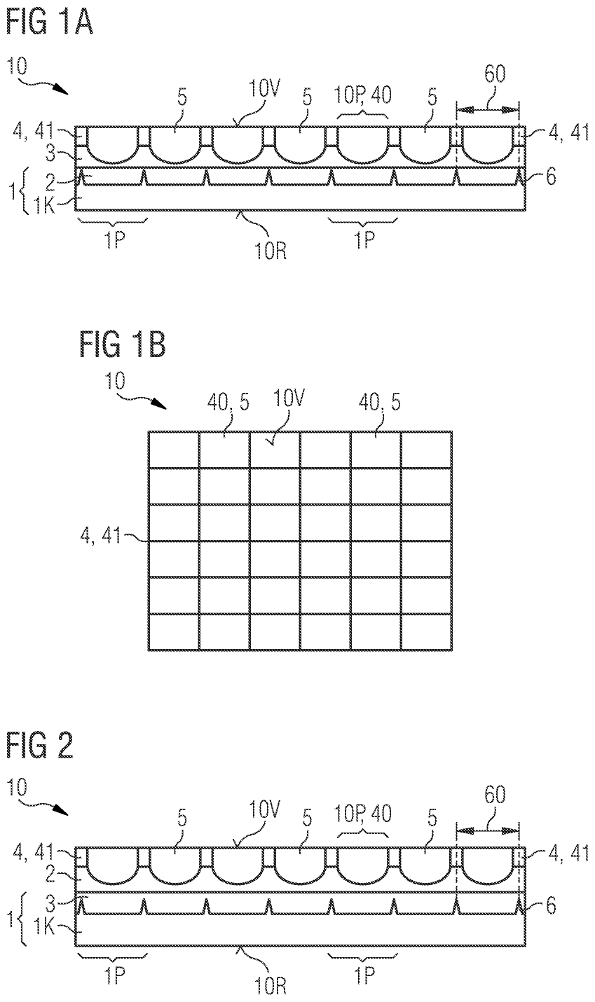

FIGS. 1A and 1B show one exemplary embodiment of a component 10. FIG. 1A schematically illustrates the component 10 in sectional view. FIG. 1B schematically illustrates the component 10 in a plan view of the front side 10V thereof.

In accordance with FIG. 1A, the component 10 has a semiconductor chip 1, a connection layer 2, a converter layer 3 and a grid structure 4. The connection layer 2 is arranged in the vertical direction between the semiconductor chip 1 and the converter layer 3. The converter layer 3 is arranged in the vertical direction between the connection layer 2 and the grid structure 4. In particular, the grid structure 4 and the converter layer 3 are produced in common process steps before the grid structure 4 and the converter layer 3 are secured on the semiconductor chip 1 by means of the connection layer 2.

The grid structure 4 has openings 4o and a grid frame 41, in particular a single continuous grid frame 41. The grid frame 41 is formed from inner and outer grid walls that laterally enclose the openings 40. The grid structure 4 can be formed from an electrically insulating material, for instance from a resist material or from a polymer, or from an electrically conductive material, for instance from a metal. In lateral directions the openings 4o are each completely enclosed by the grid frame 41. This is illustrated schematically in FIG. 1B, for example. The component 10 can have a plurality of picture elements 10P or pixels 10P. The picture elements 10P or the pixels 10P can each be uniquely assigned to one of the openings 40 of the grid structure 4, and in particular vice versa.

Optical elements 5 can be arranged in the openings 40. In particular, the optical elements 5 are optical lenses. For example, a single optical element 5 is arranged in each of the openings 40 of the grid structure 4. The converter layer 3 can adjoin, in particular directly adjoin, the grid structure 4, the optical elements 5 and/or the connection layer 2.

The openings 40 can each be completely filled by an optical element 5. In this case, the openings 40 are free of a material of the converter layer 3, in particular. In a plan view of the grid structure 4, the optical elements 5 can each be situated exclusively within one of the openings 40 of the grid structure 4. In other words, the optical elements 5 do not project laterally beyond the corresponding openings 40 of the grid structure 4.

It is possible for the converter layer 3 to be embodied in a continuous fashion or in a segmented fashion. If the converter layer 3 is embodied in a segmented fashion, the converter layer 3 can have a plurality of partial layers arranged next to one another. The partial layers of the converter layer 3 can comprise the same converter material or different converter materials. For example, the adjacent partial layers contain different phosphors configured for converting blue radiation portions or UV radiation portions into red, yellow or green radiation portions. In plan view, different openings 40 of the grid structure 4 can overlap different partial layers of the converter layer 3.

The component 10 has a front side 10V and a rear side 10R facing away from the front side 10V. The rear side 10R can be formed by an exposed surface of the semiconductor chip 1. In accordance with FIG. 1A, the front side 10V can be formed by surfaces of the grid structure 4 and of the optical elements 5. In particular, the front side 10V is embodied in a planar fashion. Along the vertical direction, the optical elements 5 can terminate flush with the grid structure 4. In other words, the optical elements 5 do not project beyond the grid structure 4 along the vertical direction away from the semiconductor chip 1. The optical elements 5 can each have a curved surface facing the converter layer 3 or the semiconductor chip 1 in accordance with FIG. 1A. In particular, the converter layer 3 indirectly or directly adjoins the curved surfaces of the optical elements 5. As illustrated schematically in FIG. 1A, the converter layer 3 has local curved surfaces facing away from the semiconductor chip 1 and facing the optical elements 5.

During operation of the component 10, the semiconductor chip 1 is configured for generating electromagnetic radiation in the UV spectral range or in the visible spectral range, for instance in the blue, green, yellow and/or red spectral range. The semiconductor chip 1 has a semiconductor body 1K based for example on a III-V compound semiconductor material or on a II-VI compound semiconductor material. The semiconductor body 1K can have a first semiconductor layer, a second semiconductor layer and an active zone arranged between the first and second semiconductor layers. In particular, the active zone forms a pn junction zone of the semiconductor body. The first semiconductor layer and the second semiconductor layer can be embodied as n-conducting and p-conducting, respectively, or vice versa.

It is possible for the semiconductor body 1K to be embodied in a continuous fashion. In this case, the active zone can be embodied in a continuous fashion or in a segmented fashion. If the active zone is embodied in a segmented fashion, the first semiconductor layer or the second semiconductor layer can likewise be segmented. The semiconductor body 1K is segmented in particular by the formation of separating trenches in the semiconductor body 1K. However, the semiconductor body 1K can still be embodied in a continuous fashion if the active zone is segmented and at least one of the semiconductor layers of the semiconductor body, for example the first semiconductor layer or the second semiconductor layer, remains continuous. Particularly on account of the segmentation, the semiconductor chip 1 can have a plurality of individually controllable partial regions 1P, each assigned to one, in particular exactly one, of the openings 40 of the grid structure 4 and configured for generating electrical radiation during operation of the component 10. Such a partial region 1P of the semiconductor chip 1 can form a picture element or pixel of the component 10.

As an alternative to the segmentation, it is possible for the semiconductor body 1K or the semiconductor chip 1 to have a plurality of laterally spaced apart partial bodies. The spatially separated partial bodies of the semiconductor body 1K or of the semiconductor chip 1 can each form one of the individually controllable partial regions 1P of the semiconductor chip 1.

In FIG. 1A, the positions of the individual partial regions 1P of the semiconductor chip 1 or of the semiconductor body 1K are identified by a marking structure 6 or a separating structure 6. The marking structure 6 can be formed by the structuring of the semiconductor body 1K, for instance by the formation of separating trenches between the individually controllable partial regions 1P of the semiconductor chip 1 or by roughening the semiconductor body 1K. It is possible for the separating trenches to be filled with an electrically insulating material, for example. The marking structure 6, which is illustrated schematically in FIG. 1A, can thus form a separating structure 6 with further openings 60, wherein the separating structure 6 can be formed from a plurality of separating trenches or from a plurality of separating trenches filled with an electrically insulating material.

By virtue of the marking structure 6 or by virtue of the separating structure 6, the positions of the individually controllable partial regions 1P forming in particular the individual pixels of the semiconductor chip 1 are recognizable, in particular recognizable from outside. Preferably, the openings 40 of the grid structure 4 and the openings 60 of the marking structure 6 are matched to one another. For example, each of the openings 40 is assigned to exactly one of the openings 60, and vice versa. The partial regions 1P of the semiconductor chip 1 are thus coordinated with the openings 40 of the grid structure 4 with regard to their positions and sizes.

As illustrated schematically in FIG. 1A, the marking structure 6 can have elevations on the semiconductor body 1K. The elevations can form a grid on the semiconductor body 1K. The grid can be interrupted in the pixel corners, such that a material of the connection layer 2, for instance an adhesive material or an adhesive silicone, can spread uniformly on the semiconductor body 1K. In a departure from FIG. 1A, it is possible for the marking structure 6 to have depressions in the semiconductor body 1K, instead of the elevations. The depressions can be formed by roughening the semiconductor body 1K. Even if the depressions or elevations have a depth or height of just a few micrometers, for example between 0.5 μm and 5 μm inclusive or between 1 μm and 2 μm inclusive, the effects which are caused by the connection layer 2 and which possibly impair the contrast between the adjacent pixels 10P can be counterbalanced. As illustrated schematically in FIG. 1A, the marking structure 6 can be partly arranged in the connection layer 2.

The connection layer 2 is formed in particular from an electrically insulating and radiation-transmissive material. In particular, the connection layer 2 is formed from an adhesive material, for instance from an adhesive silicone. It is possible for scattering particles or reflective particles to be embedded in the adhesive material. For example, the connection layer 2 is embodied with regard to its material composition and its vertical layer thickness in such a way that at least 80%, 90% or 95% of the electromagnetic radiation impinging on it is transmitted. For example, the connection layer 2 has a vertical layer thickness that is between 10 nm and 300 μm inclusive, for example between 10 nm and 100 μm inclusive, between 10 nm and 50 μm inclusive, or between 10 nm and 10 μm inclusive. Moreover, it is possible for the connection layer 2 to have a larger vertical layer thickness or for the component 10 to be free of such a connection layer 2.

FIG. 1B shows the component 10 in a plan view. In particular, the grid structure 4 on the front side 10V of the component 10 is recognizable from outside. On the front side 10V, the openings 40 and the grid frame 41 of the grid structure 4 are formed by suitable arrangement of grid lines or grid walls of two groups, wherein the grid lines or grid walls of the same group run parallel or substantially parallel to one another and the grid lines or grid walls of different groups run transversely or perpendicularly to one another. The number of openings 40 can be different depending on the size of the semiconductor chip 10.

The exemplary embodiment of a component 10 illustrated in FIG. 2 substantially corresponds to the exemplary embodiment illustrated in FIG. 1A. In contrast thereto, the positions and/or the geometries of the converter layer 3 and of the connection layer 2 are mutually interchanged. The connection layer 2 can adjoin directly the grid structure 4, the converter layer 3 and/or directly the optical elements 5. In accordance with FIG. 2, the connection layer 2 is situated in the vertical direction between the grid structure 4 and the converter layer 3. In particular, the converter layer 3 is applied to the semiconductor chip 1 before the process of securing the grid structure 4 on the semiconductor chip 1. The grid structure 4 is thus produced separately from the converter layer 3 and from the semiconductor chip 1. It is only after the completion of the grid structure 4 that the latter is secured on the converter layer 3 by means of the connection layer 2.

In accordance with FIG. 2, the marking structure 6 or the separating structure 6 is situated regionally within the converter layer 3. In particular, the openings 60 of the marking structure 6 are filled, for example completely filled, by the material of the converter layer 3.

In particular, the converter layer 3 is embodied in a continuous fashion. In a plan view of the semiconductor chip 1, the converter layer 3 can completely cover the marking structure 6 situated underneath. In a departure therefrom, it is possible for the marking structure 6 to extend through the converter layer 3 along the vertical direction. In this case, the converter layer 3 can have a plurality of separate partial layers arranged in each case in different openings 60 of the marking structure 6. The partial layers of the converter layer 3 can comprise the same phosphors or different phosphors.

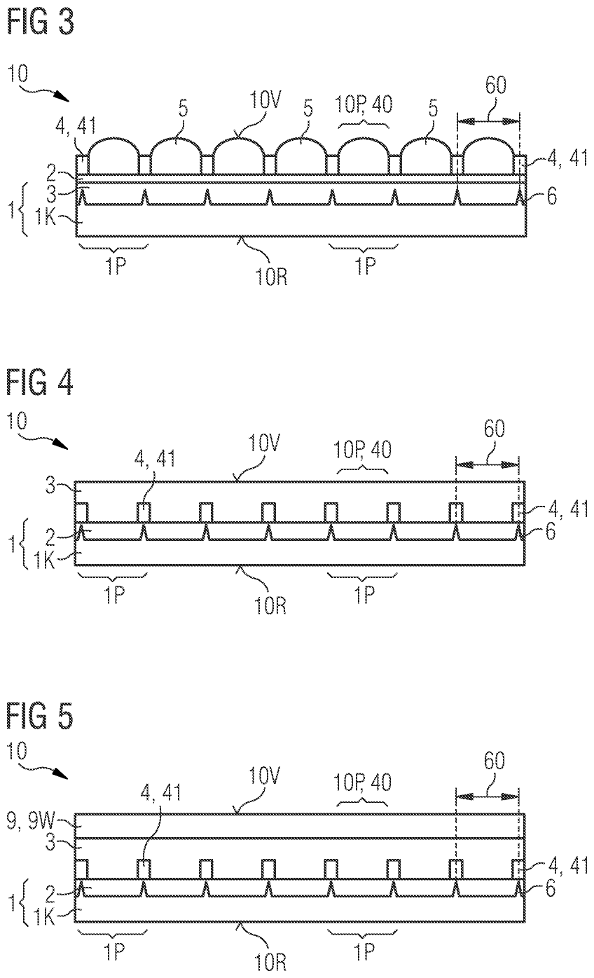

The exemplary embodiment illustrated in FIG. 3 substantially corresponds to the exemplary embodiment of a component 10 illustrated in FIG. 2. In contrast thereto, the optical elements 5 have curved surfaces which, in contrast to FIG. 2, face away from the connection layer 2 rather than face the latter. The front side 10V of the component 10 can be formed regionally by the curved surfaces of the optical elements 5. In contrast to the exemplary embodiment in accordance with FIG. 2, in which the connection layer 2 regionally reproduces the curved surfaces of the optical elements 5 and thus has regionally different layer thicknesses, the connection layer 2 in accordance with FIG. 3 has a substantially constant vertical layer thickness. In comparison with FIG. 2, the connection layer 2 in accordance with FIG. 3 can be made particularly thin.

Entirely analogously to FIG. 3, the optical elements 5 illustrated in FIG. 1A can be arranged in such a way that they have curved surfaces facing away from the converter layer 3 rather than facing the latter.

The exemplary embodiment illustrated in FIG. 4 substantially corresponds to the exemplary embodiment of a component 10 illustrated in FIG. 1A. In contrast, the component 10 is free of optical elements 5. The front side 10V of the component 10 is formed in particular by an exposed surface of the converter layer 3. The openings 40 of the grid structure 4 are filled, in particular completely filled, by the material of the converter layer 3. In a plan view of the semiconductor chip 1, the converter layer 3 in particular completely covers the grid structure 4. As a further difference with respect to FIG. 1A, the grid structure 4 in accordance with FIG. 4 in particular directly adjoins the connection layer 2. In accordance with FIG. 1A, the grid structure 4 is spaced apart spatially from the connection layer 2 at least by the converter layer 3.

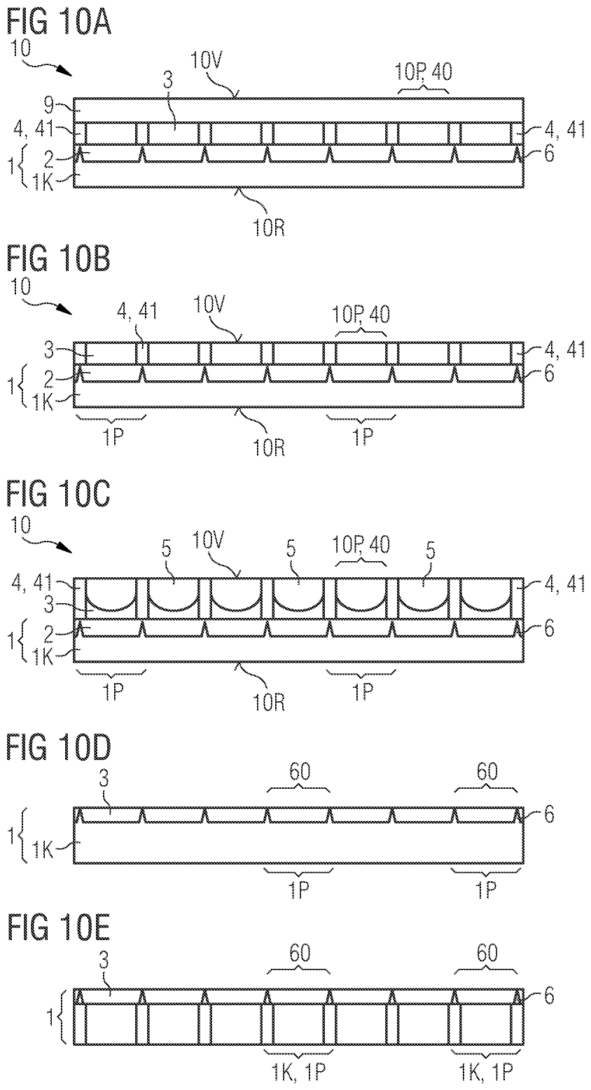

In a departure from FIG. 4, it is possible for the grid structure 4 to extend through the converter layer 3. This is illustrated schematically in FIG. 10B, for example. The converter layer 3 can have a plurality of laterally spaced apart partial layers arranged in each case in different openings 40 of the grid structure 4. The partial layers of the converter layer 3 can comprise the same phosphors or different phosphors. In particular, two, three or four adjacent openings 40 can comprise different phosphors configured for converting electromagnetic radiation portions of short wavelength into different portions of long wavelength. Each of the openings 40 of the grid structure 4 can be uniquely assigned to a single picture element or pixel 10P of the component 10, and in particular vice versa.

The exemplary embodiment illustrated in FIG. 5 substantially corresponds to the exemplary embodiment of a component 10 illustrated in FIG. 4. In contrast thereto, the component 10 has an auxiliary carrier 9 or 9W, wherein the grid structure 4 is arranged in a vertical direction between the auxiliary carrier 9 or 9W and the connection layer 2. The auxiliary carrier 9 or 9W is preferably embodied as radiation-transmissive. The front side 10V of the component 10 is formed in particular by an exposed surface of the auxiliary carrier 9 or 9W. In accordance with FIG. 5, the grid structure 4 is spatially separated from the auxiliary carrier 9 or 9W by the converter layer 3. In a departure therefrom, it is possible for the grid structure 4 to directly adjoin the auxiliary carrier 9 or 9W. This is illustrated schematically in FIG. 10A, for example.

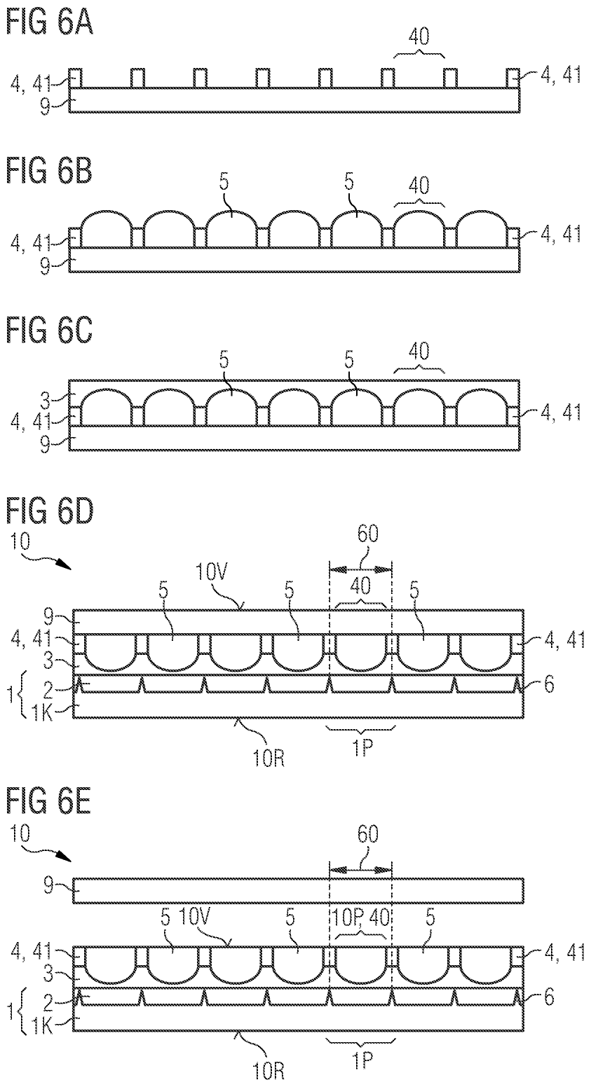

FIGS. 6A, 6B, 6C, 6D and 6E describe some method steps for producing a component 10 in particular in accordance with FIG. 1A.

Firstly, an auxiliary carrier 9 in particular with the grid structure 4 arranged thereon is provided. The grid structure 4 comprising the grid frame 41 can be adhesively bonded, directly produced, deposited or formed by means of an electrolytic method on the auxiliary carrier 9. For example, the grid structure 4 is produced photolithographically, in particular in combination with a sputtering or electroplating process. It is possible for a sacrificial layer to be arranged in a vertical direction between the auxiliary carrier 9 and the grid structure 4. In a later method step, the auxiliary carrier 9 can be removed from the grid structure 4 in particular at the sacrificial layer, for example by means of a mechanical, chemical or laser-induced separating process.

The auxiliary carrier 9 can be embodied as radiation-transmissive, radiation-semitransmissive or radiation-nontransmissive. For example, the auxiliary carrier 9 is a sapphire substrate. If the auxiliary carrier 9 is embodied as radiation-transmissive or radiation-semitransmissive, the auxiliary carrier 9 can be detached from the grid structure 4 for instance by means of a laser lift-off process. If the auxiliary carrier 9 is embodied as radiation-transmissive, it is conceivable for the auxiliary carrier 9 to remain on the component 10 after the completion of the component 10.

In accordance with FIG. 6B, optical elements 5 are formed on the auxiliary carrier 9. In particular, the optical elements 5 are produced by jetting or metering into the openings 40. The optical elements 5 can be optical lenses. In particular, the optical elements 5 are each assigned to a single picture element or pixel 10P of the component 10, and in particular vice versa. The optical element 5, in particular the lens 5, is configured for instance for focusing the light in the pixel and can provide for additional contrast enhancement. In a plan view of the auxiliary carrier 9, the optical elements 5 are situated in lateral directions within, in particular completely within, the openings 40 of the grid structure 4. Along the vertical direction the optical elements 5 can project beyond the grid structure 4.

In accordance with FIG. 6C, the converter layer 3 is applied to the grid structure 4 and to the optical elements 5. For example, the converter layer 3 is sprayed onto the auxiliary carrier 9. The converter layer 3 in particular directly adjoins the grid structure 4 and the optical elements 5. The auxiliary carrier 9 with the grid structure 4 arranged thereon can be singulated into smaller units before the grid structure 4 is secured on a semiconductor chip 1 for instance by means of a connection layer 2. The smaller units can be referred to as singulated grid-converter laminae. The grid structure 4 is thus completed separately from a semiconductor chip 1 before it is applied to the semiconductor chip 1.

FIG. 6D shows the component 10 after the grid structure 4 has been secured on the semiconductor chip 1 by means of the connection layer 2. The grid-converter lamina illustrated in FIG. 6 is firstly turned over and arranged on the semiconductor chip 1 in such a way that the converter layer 3 is situated between the semiconductor chip 1 and the grid structure 4. If the auxiliary carrier 9 is embodied as radiation-transmissive, it is possible for it to remain on the completed component 10.

In accordance with FIG. 6D, the grid structure 4 and the marking structure 6 are coordinated with one another in such a way that the openings 40 of the grid structure 4 are each uniquely assigned to one of the openings 60 of the marking structure 6, and in particular vice versa. The relative alignment of the openings 40 with the openings 60 is ensured by optical recognition, for example. In particular, the openings 60 of the marking structure 6 and the corresponding openings 40 of the grid structure 4 have approximately the same sizes within the production tolerances.

The semiconductor chip 1 is in particular a segmented or pixelated semiconductor chip 1. The semiconductor chip 1 can have a plurality of individually controllable partial regions 1P, wherein the positions of the partial regions 1P are identified for example by the openings 60 of the marking structure 6. The individual picture element 10P or the individual pixel 10P of the component 10 has in particular exactly one such partial region 1P, which for example is assigned to exactly one of the openings 60 of the marking structure 6 and to exactly one of the openings 40 of the grid structure 4.

The exemplary embodiment illustrated in FIG. 6E substantially corresponds to the exemplary embodiment of a component 10 illustrated in FIG. 6D. In contrast thereto, the auxiliary carrier 9 is removed from the grid structure 4, for example by means of a mechanical, chemical or laser-induced separating process.

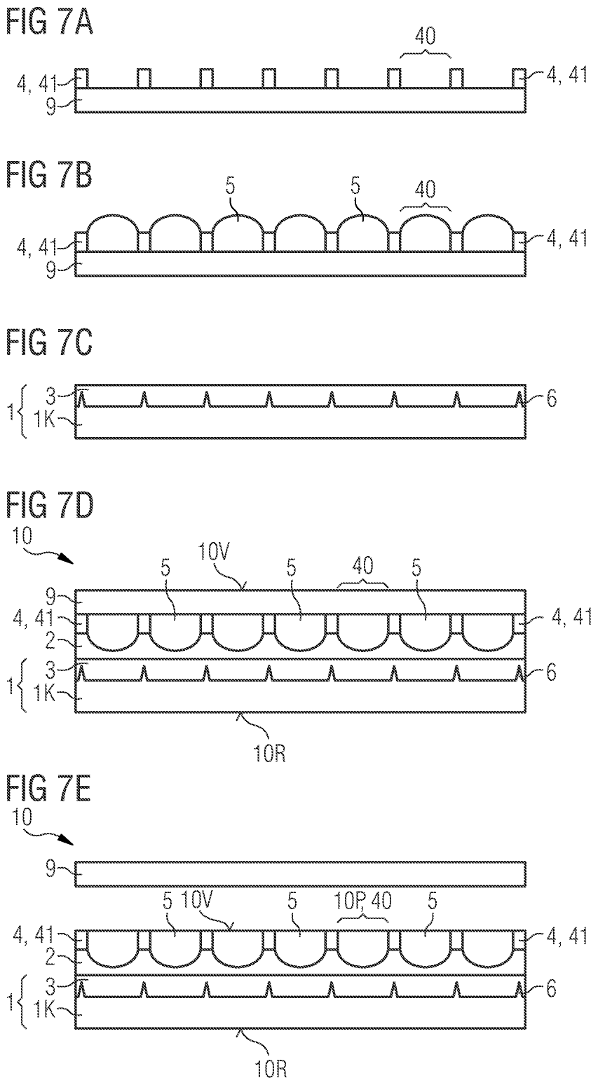

FIGS. 7A, 7B, 7C, 7D and 7E show some method steps for producing a component 10 described in particular in FIG. 2.

The method steps illustrated in FIGS. 7A and 7B correspond to the method steps illustrated in FIGS. 6A and 6B.

In accordance with FIG. 7C, a semiconductor chip 1 with a converter layer 3 arranged thereon is provided. The converter layer 3 is applied in particular directly to the semiconductor chip 1. In contrast to FIG. 6C, the converter layer 3 is formed in the presence of the semiconductor chip 1 in accordance with FIG. 7C, rather than in the presence of the grid structure 4.

In accordance with FIG. 7D, the auxiliary carrier 9 with the grid structure 4 arranged thereon is secured on the converter layer 3 by means of a connection layer 2. In a subsequent method step, the auxiliary carrier 9 can be detached from the component 10, in particular from the grid structure 4. The method steps described in FIGS. 7D and 7E substantially correspond to the method steps shown in FIGS. 6D and 6E, but with different relative positions of the converter layer 3 and of the connection layer 2 with respect to the grid structure 4 or to the semiconductor chip 1.

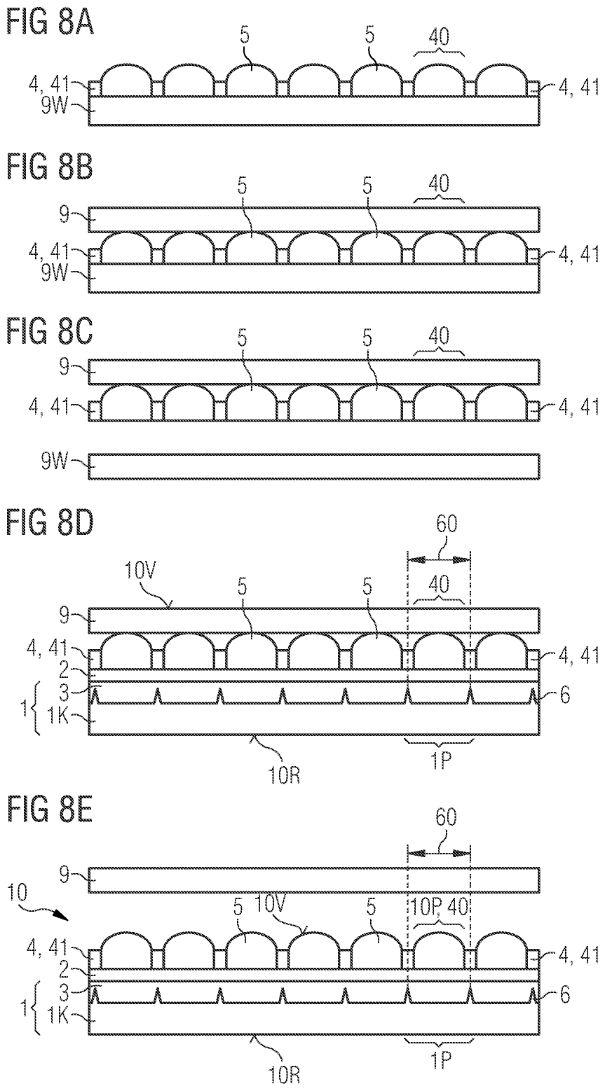

FIGS. 8A, 8B, 8C, 8D and 8E show some method steps for producing a component 10 illustrated schematically in FIG. 3, in particular.

The method step illustrated in FIG. 8A substantially corresponds to the method step illustrated in FIG. 6B or 7B. In contrast thereto, the grid structure 4 is formed on a temporary carrier 9W or on a temporary auxiliary carrier 9W, which is detached from the grid structure 4 before the process of applying the grid structure 4 to the semiconductor chip 1. The material of the temporary carrier 9W can be as desired and is selected in particular in such a way that the process of forming the grid structure 4 or the optical elements 5 on the temporary carrier 9W is fostered.

In accordance with FIG. 8B, the auxiliary carrier 9 is applied to the grid structure 4 or to the optical elements 5 in such a way that the grid structure 4 is arranged in a vertical direction between the auxiliary carrier 9 and the temporary carrier 9W. The grid structure 4 and the optical elements 5 are transferred by adhesive bonding on the auxiliary carrier 9, for example. After the auxiliary carrier 9 has been applied, the temporary carrier 9W is removed from the grid structure 4 in accordance with FIG. 8C.

The method steps illustrated in FIGS. 8D and 8E substantially correspond to the method steps illustrated in FIGS. 7D and 7E. In contrast thereto, the optical elements 5 have curved surfaces facing the auxiliary carrier 9 and facing away from the connection layer 2. The use of the temporary carrier 9W thus makes it possible to obtain a particularly smooth connection surface directly adjoining the connection layer 2, as a result of which the connection layer 2 can be made particularly thin. This affords the advantage that less adhesive material is required and the thermal linking of the grid structure 4 or of the converter layer 3 to the semiconductor chip 1 is improved.

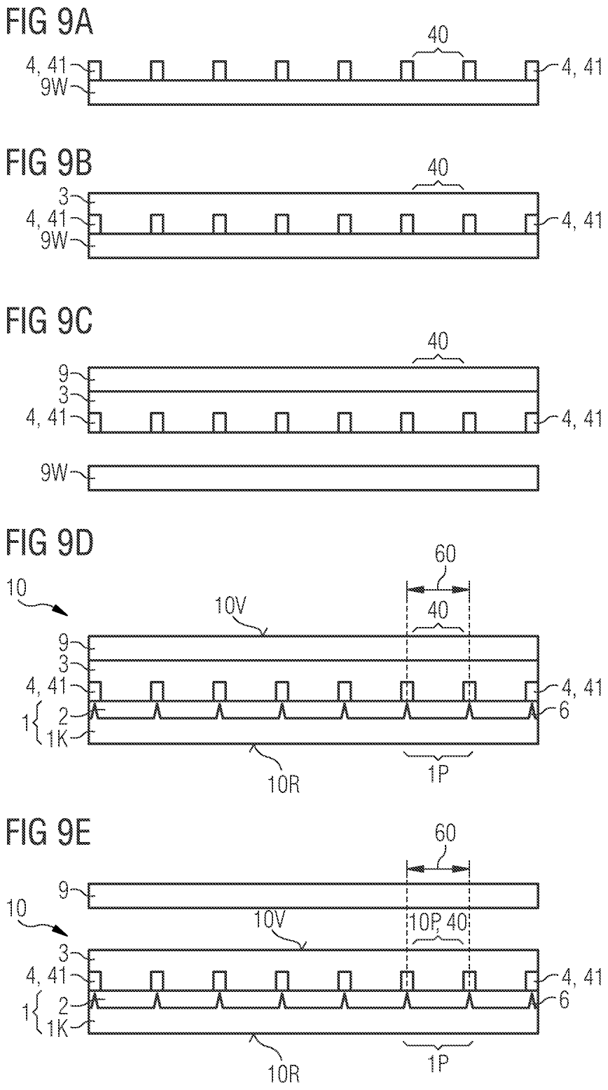

FIGS. 9A, 9B, 9C, 9D and 9E show some further method steps for producing a component 10 illustrated schematically in FIG. 4 or in FIG. 5, for example.

The method step illustrated in FIG. 9A substantially corresponds to the method step illustrated in FIG. 8A, but without the optical elements 5.

In accordance with FIG. 9B, the converter layer 3 is applied, in particular sprayed, onto the grid structure 4 and onto the temporary carrier 9W. In a plan view of the temporary carrier 9W, the converter layer 3 in particular completely covers the grid structure 4.

The method step illustrated in FIG. 9C substantially corresponds to the combination of the method steps illustrated in FIGS. 8B and 8C, wherein firstly the auxiliary carrier 9 is applied to the grid structure 4 or to the converter layer 3 before the temporary carrier 9W is detached.

In accordance with FIG. 9D, the grid structure 4, the converter layer 3 and the auxiliary carrier 9, analogously to those in FIG. 6D, 7D or 8D, are secured on the semiconductor chip 1 by means of the connection layer 2. The auxiliary carrier 9 can remain on the completed component 10 or—as illustrated schematically in FIG. 9E—can subsequently be removed.

The exemplary embodiment illustrated in FIG. 10A substantially corresponds to the exemplary embodiment of a component 10 illustrated in FIG. 9D. In contrast thereto, the grid structure 4 extends through the converter layer 3 along the vertical direction. This embodiment of the component 10 can be attained if the converter layer 3 illustrated in FIG. 9B, for instance, is firstly produced extensively planar and subsequently ground down before the auxiliary carrier 9 is applied to the converter layer 3. Grinding down the converter layer 3 can additionally serve for color locus control or color locus setting. Moreover, this gives rise to a smooth adhesive bonding surface being available, which no longer requires a further step of transfer by adhesive bonding.

The exemplary embodiment illustrated in FIG. 10B substantially corresponds to the exemplary embodiment of a component 10 illustrated in FIG. 10A. In contrast thereto, the auxiliary carrier 9 is not present. The front side 10V of the component 10 can be formed regionally by surfaces of the grid structure 4 and regionally by surfaces of the converter layer 3. In accordance with FIGS. 10A and 10B, the converter layer 3 can be situated completely within the openings 40 of the grid structure 4. In particular, the grid structure 4 is embodied in a continuous fashion. For example, the grid frame 41 does not have any interruptions. In this case, the converter layer 3 can be divided into a plurality of partial layers arranged in each case in one of the openings 40 of the grid structure 4.

The exemplary embodiment illustrated in FIG. 10C substantially corresponds to the exemplary embodiment of a component 10 illustrated in FIG. 1A. In contrast thereto, the grid structure 4, entirely analogously to the exemplary embodiments illustrated in FIGS. 10A and 10B, extends through the converter layer 3 along the vertical direction.

FIG. 10D shows a further embodiment of a semiconductor chip 1 with the converter layer 3 arranged thereon. This embodiment substantially corresponds to the embodiment illustrated in FIG. 7C. In contrast thereto, the marking structure 6 extends through the converter layer 3 along the vertical direction. Analogously to the exemplary embodiments illustrated in FIGS. 10A and 10B, the converter layer 3 can be divided into a plurality of partial layers arranged in each case in one of the openings 60 of the marking structure 6.

The embodiment illustrated in FIG. 10E substantially corresponds to the embodiment of a semiconductor chip 1 illustrated in FIG. 10D. In contrast thereto, it is possible for the semiconductor body 1K not to be embodied in a continuous fashion, but rather to have a plurality of laterally spaced apart partial regions 1P. The partial regions 1P can be separated from one another by separating trenches of the marking structure 6, which are filled with an electrically insulating material, for example. The partial regions 1P are in particular individually controllable. In other words, the partial regions 1P can be controlled independently of one another.

By virtue of the grid structure 4 and/or the converter layer 3 being produced separately from the semiconductor chip 1, it is possible to characterize a converter element in particular in the form of a converter lamina before it is transferred to the semiconductor chip 1. The yield can be increased in this way. Moreover, it is possible to enhance the contrast between the pixels 10P of the component 10 by means of the grid structure 4 and/or by means of the optical elements 5 arranged in the openings 40 of the grid structure 4. In all of the exemplary embodiments, it is possible for the connection layer to be embodied as an independent layer or as a partial layer of the converter layer.

The invention is not restricted to the exemplary embodiments by the description of the invention on the basis of said exemplary embodiments. Rather, the invention encompasses any novel feature and also any combination of features, which in particular includes any combination of features in the claims, even if this feature or this combination itself is not explicitly specified in the claims or exemplary embodiments.

1.-20. (canceled)

21. A component comprising:
a semiconductor chip;
a converter layer; and
a grid structure,
wherein the semiconductor chip is configured to generate electromagnetic radiation,
wherein the converter layer is configured to convert at least one portion of the electromagnetic radiation,
wherein the grid structure is configured to suppress lateral optical crosstalk, the grid structure having a grid frame and openings enclosed by the grid frame,
wherein the grid structure only adjoins the converter layer,
wherein the openings of the grid structure are free of a material of the converter layer, and
wherein optical elements are arranged in the openings.

22. The component as claimed in claim 21, further comprising an electrically insulating and radiation-transmissive connection layer, wherein the connection layer is arranged in a vertical direction between the semiconductor chip and the grid structure, and wherein the connection layer is embodied as an independent layer or as a partial layer of the converter layer.

23. The component as claimed in claim 22, wherein the connection layer is arranged in the vertical direction between the converter layer and the grid structure such that the grid structure is spaced apart vertically from the converter layer.

24. The component as claimed in claim 22, wherein the connection layer is formed from an adhesive material with scattering particles embedded therein.

25. The component as claimed in claim 21, wherein the grid structure is formed from an electrically insulating material.

26. The component as claimed in claim 21, wherein the grid structure is formed from an electrically conductive material.

27. The component as claimed in claim 21, wherein the semiconductor chip has a continuous semiconductor body embodied in a segmented fashion such that the semiconductor chip has a plurality of individually controllable partial regions, each assigned to one of the openings of the grid structure and configured to generate the electromagnetic radiation.

28. The component as claimed in claim 21, wherein the semiconductor chip has a plurality of semiconductor bodies spatially separated from one another and configured to generate the electromagnetic radiation, and wherein the spatially separated semiconductor bodies are each assigned to one of the openings of the grid structure.

29. The component as claimed in claim 21, wherein the optical elements extend regionally into the converter layer.

30. The component as claimed in claim 21, wherein each of the openings has a maximum lateral extent that is between 0.5 μm and 5 cm, inclusive.

31. The component as claimed in claim 21, wherein the semiconductor chip has a marking structure defining boundaries between different partial regions of the semiconductor chip, and wherein the partial regions of the semiconductor chip are each assigned to one of the openings of the grid structure.

32. A method for producing a component, the method comprising:
providing a semiconductor chip configured to generate electromagnetic radiation;
providing an auxiliary carrier;
forming a grid structure on the auxiliary carrier, wherein the grid structure is configured to suppress lateral optical crosstalk, has a grid frame and openings enclosed by the grid frame;
forming a converter layer on the semiconductor chip or on the grid structure; and
connecting the grid structure to the semiconductor chip.

33. The method as claimed in claim 32, wherein the grid structure only adjoins the converter layer, wherein the openings of the grid structure are free of a material of the converter layer, and wherein optical elements are arranged in the openings.

34. The method as claimed in claim 32, further comprising arranging a connection layer in a vertical direction between the converter layer and the grid structure such that the grid structure is spaced apart vertically from the converter layer.

35. The method as claimed in claim 32, further comprising removing the auxiliary carrier from the component after connecting the grid structure to the semiconductor chip.

36. The method as claimed in claim 32, further comprising removing the auxiliary carrier from the grid structure before the connecting the grid structure to the semiconductor chip.

37. The method as claimed in claim 32,
wherein, before connecting the grid structure to the semiconductor chip, the converter layer is formed on the grid structure such that openings of the grid structure are filled by a material of the converter layer,
wherein the grid structure is connected to the semiconductor chip by an electrically insulating and radiation-transmissive connection layer, and
wherein, after connecting the grid structure to the semiconductor chip, the connection layer is arranged between the converter layer and the semiconductor chip.

38. The method as claimed in claim 32,
wherein optical elements are formed in the openings of the grid structure,
wherein, before connecting the grid structure to the semiconductor chip, the converter layer is formed on the grid structure and on the optical elements,
wherein the grid structure is connected to the semiconductor chip by an electrically insulating and radiation-transmissive connection layer, and
wherein, after connecting the grid structure to the semiconductor chip, the connection layer is arranged between the converter layer and the semiconductor chip.

39. The method as claimed in claim 32,
wherein, before connecting the grid structure to the semiconductor chip, the converter layer is formed on the semiconductor chip,
wherein the grid structure is connected to the semiconductor chip by an electrically insulating and radiation-transmissive connection layer, and
wherein, after connecting the grid structure to the semiconductor chip, the connection layer is arranged between the converter layer and the grid structure.

40. The method as claimed in claim 32,
wherein the auxiliary carrier a temporary carrier,
wherein, after forming the grid structure on the temporary carrier, a further auxiliary carrier is applied to the grid structure such that the grid structure is situated between the temporary carrier and the further auxiliary carrier, and
wherein the temporary carrier is removed from the grid structure before the grid structure is connected to the semiconductor chip a connection layer.
